(19) United States
(12) Patent Application Publication
(10) Pub. No.: US 2024/0021486 A1
(43) Pub. Date: Jan. 18, 2024

(54) PRINTED CIRCUIT BOARD

(71) Applicant: SAMSUNG ELECTRO-MECHANICS CO., LTD., Suwon-si (KR)

(72) Inventors: Myeong Hui Jung, Suwon-si (KR); Sang Hoon Kim, Suwon-si (KR); Kee Su Jeon, Suwon-si (KR); Ki Eun Cho, Suwon-si (KR); Min Jae Seong, Suwon-si (KR)

(73) Assignee: SAMSUNG ELECTRO-MECHANICS CO., LTD., Suwon-si (KR)

(21) Appl. No.: 18/195,027

(22) Filed: May 9, 2023

(30) Foreign Application Priority Data
Jul. 18, 2022 (KR) 10-2022-0088227

(51) Int. Cl. H01L 23/13; H01L 25/16; H01L 23/498; H01L 21/48

(52) U.S. Cl. CPC H01L 23/13; H01L 25/16; H01L 23/49838; H01L 21/4846

(57) ABSTRACT

A printed circuit board includes a first insulating layer, a wiring pattern disposed in an upper side of the first insulating layer, a second insulating layer disposed on an upper surface of the first insulating layer and having a cavity exposing the wiring pattern, and an insulating pattern disposed between the first and second insulating layers, and having a side surface partially exposed by the cavity, while having an upper surface entirely covered by the second insulating layer.

### CROSS-REFERENCE TO RELATED APPLICATION(S)

This application claims benefit of priority to Korean Patent Application No. 10-2022-0088227 filed on Jul. 18, 2022 in the Korean Intellectual Property Office, the disclosure of which is incorporated herein by reference in its entirety.

### TECHNICAL FIELD

The present disclosure relates to a printed circuit board.

### BACKGROUND

Recently, in order to reduce the overall thickness of a package, miniaturization and thinning of a printed circuit board have been continuously required. To meet these demands, a technology for mounting electronic components by forming cavities in printed circuit boards has been developed. However, in the current technology, the exposed pad may be damaged in most cavity formation process, and in addition, it may be difficult to improve yield due to occurrence of a foot in the cavity, and thus, improvement is required.

### SUMMARY

An aspect of the present disclosure is to provide a printed circuit board in which damage to wiring patterns exposed by cavities and footings in cavities may be prevented.

An aspect of the present disclosure is to form a cavity in a substrate by applying an insulating material such as thermosetting resist ink or the like to a cavity formation area to protect the wiring pattern, forming the cavity by laser processing using CO₂ drilling or the like, and then by removing an insulating material remaining in the cavity.

According to an aspect of the present disclosure, a printed circuit board includes a first insulating layer; a wiring pattern disposed in an upper side of the first insulating layer; a second insulating layer disposed on an upper surface of the first insulating layer and having a cavity exposing the wiring pattern; and an insulating pattern disposed between the first and second insulating layers, and having a side surface partially exposed by the cavity, while having an upper surface entirely covered by the second insulating layer.

According to an aspect of the present disclosure, a printed circuit board includes a first insulating layer; a wiring pattern disposed in an upper side of the first insulating layer; a second insulating layer disposed on an upper surface of the first insulating layer and having a cavity exposing the wiring pattern; and an insulating pattern disposed along a wall surface of the cavity, at least partially buried in the second insulating layer, and including a thermosetting resist material.

According to an aspect of the present disclosure, a printed circuit board includes a first insulating layer; a wiring pattern protruding from an upper surface of the first insulating layer; an insulating pattern protruding from the upper surface of the first insulating layer; and a second insulating layer disposed on the upper surface of the first insulating layer to cover the insulating pattern and having a cavity exposing the wiring pattern and at least a portion of the insulating pattern.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a schematic cross-sectional view of an example of a printed circuit board;

FIG. 4 is a schematic cross-sectional view taken along line A-A′ in plan view of the printed circuit board of FIG. 3;

FIGS. 5 to 10 are process cross-sectional views schematically illustrating an example of manufacturing the printed circuit board of FIG. 3; and

FIG. 11 is a schematic cross-sectional view of another example of a printed circuit board.

### DETAILED DESCRIPTION

Hereinafter, the present disclosure will be described with reference to the accompanying drawings. The shapes and sizes of elements in the drawings may be exaggerated or reduced for clearer description.

Electronic Device

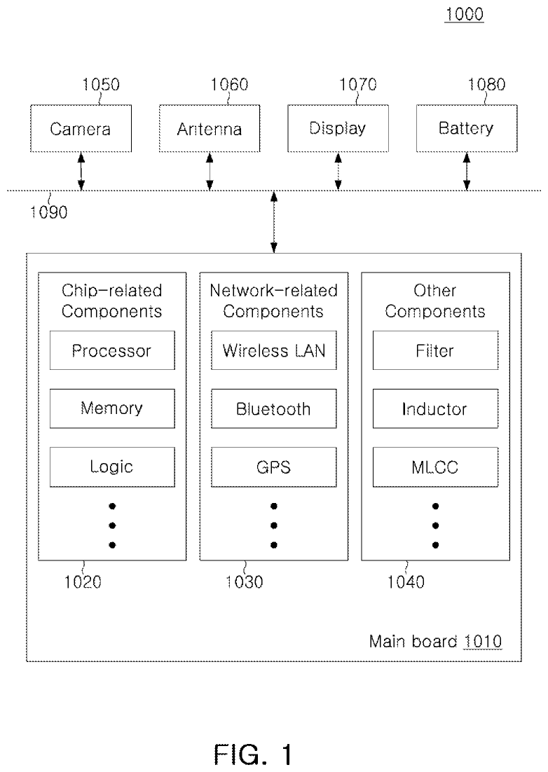

FIG. 1 is a block diagram schematically illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to other electronic components to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related electronic components 1020 are not limited thereto, but may also include other types of chip related electronic components. In addition, the chip related components 1020 may be combined with each other. The chip-related component 1020 may be in the form of a package including the aforementioned chip or electronic component.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive elements in the form of chip components used for various other purposes or the like. In addition, other components 1040 may be combined with the chip related components 1020 and/or the network related components 1030, of course.

Depending on a type of the electronic device 1000, the electronic device 1000 may include other electronic components that may or may not be physically or electrically connected to the mainboard 1010. Examples of these other electronic components may include, for example, a camera module 1050, an antenna module 1060, a display device 1070, a battery 1080, and the like, but without being limited thereto, also include an audio codec, a video codec, a power amplifier, a compass, an accelerometer, a gyroscope, a speaker, a mass storage unit (for example, a hard disk drive), a compact disk (CD) drive, a digital versatile disk (DVD) drive, and the like. These other components may also include other electronic components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

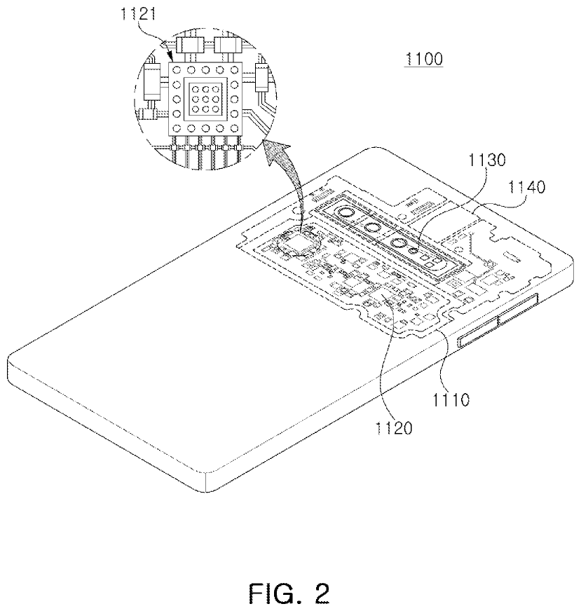

FIG. 2 is a schematic perspective view illustrating an example of an electronic device.

Referring to FIG. 2, an electronic device may be, for example, a smartphone 1100. A motherboard 1110 may be accommodated inside the smartphone 1100, and various components 1120 may be physically or electrically connected to the motherboard 1110. In addition, other components that may or may not be physically and/or electrically connected to the motherboard 1110, such as a camera module 1130 and/or a speaker 1140, may be accommodated in the inside of the smartphone. Some of the components 1120 may be the aforementioned chip-related components, for example, a component package 1121, but is not limited thereto. The component package 1121 may be in the form of a printed circuit board on which electronic components including active components and/or passive components are surface mounted. Alternatively, the component package 1121 may be in the form of a printed circuit board in which active components and/or passive components are embedded. On the other hand, the electronic device is not necessarily limited to the smartphone 1100, and may be other electronic devices as described above, of course.

Printed Circuit Board

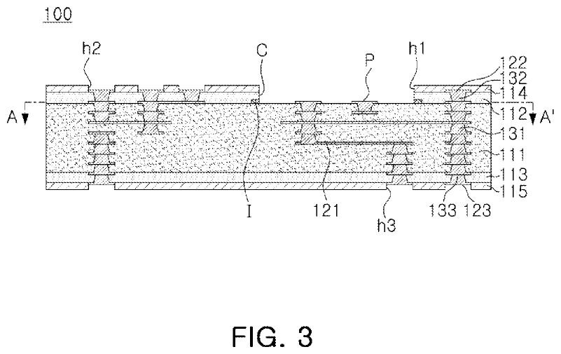

FIG. 3 is a cross-sectional view schematically illustrating an example of a printed circuit board.

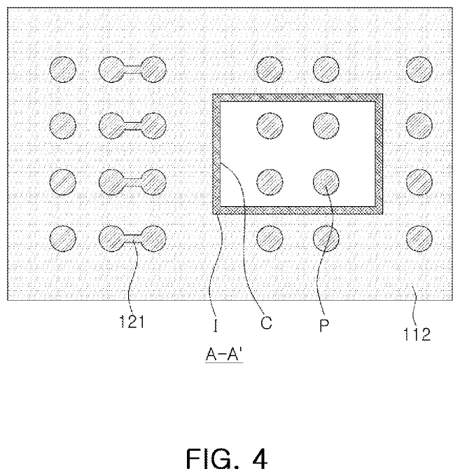

FIG. 4 is a schematic A-A′ cut plan view of the printed circuit board of FIG. 3.

Referring to the drawings, a printed circuit board 100 according to an example includes a first insulating layer 111, a wiring pattern (P) disposed in the upper side of the first insulating layer 111, a second insulating layer 112 disposed on the upper surface of the first insulating layer 111 and having a cavity (C) exposing the wiring pattern (P), and an insulating pattern (I) disposed between the first and second insulating layers 111 and 112. Disposing the wiring pattern (P) in the upper side of the first insulating layer 111 may include both a case in which the wiring pattern (P) protrudes from the upper surface of the first insulating layer 111, and a case in which the wiring pattern (P) is buried in the upper side of the first insulating layer 111 and the upper surface is exposed from the upper surface of the first insulating layer 111.

The insulating pattern (I) may be disposed along the wall surface of the cavity (C). For example, the insulating pattern (I) may be disposed to surround the cavity (C). At least a portion of the insulating pattern (I) may be buried in the second insulating layer 112, and a portion of the side surface is exposed by the cavity (C), but the upper surface may not be exposed. For example, the insulating pattern (I) is disposed on the upper surface of the first insulating layer 111 and buried in the second insulating layer 112, and a portion of the side surface is exposed from the second insulating layer 112, but the remaining portion of the side surface and the entire upper surface may be covered with the second insulating layer 112.

As will be described later, as described below, a structural feature may be derived as a result of processes, for example, in which an insulating material such as thermosetting resist ink is applied on the first insulating layer 111 to protect the wiring pattern (P), and thereafter, after forming the second insulating layer 112 on the first insulating layer 111, the cavity (C) is processed by laser processing using a CO₂ drill or the like, and then, the insulating pattern (I) is formed by removing the insulating material remaining in the cavity (C). In this case, damage to the wiring pattern (P) may be prevented in the process of processing the cavity (C), thereby increasing the product yield. In addition, a lifting phenomenon may be prevented, and furthermore, an illuminance deviation between the first insulating layer 111 and the wiring pattern (P) may be improved. In one example, an inclination angle of a wall surface of the cavity (C) with respect to the upper surface of the first insulating layer 111 may be greater than an inclination angle of a wall surface of the second via 132 with respect to the upper surface of the first insulating layer 111. That is, the wall surface of the cavity (C) may be relatively vertical with respect to the upper surface of the first insulating layer 111, and thus, the foot in the cavity (C) may also be prevented by further strengthening the laser processing conditions, and the degree of freedom of board design may be improved. In addition, the laser processing unit cost for formation of the cavity (C) may be improved.

The insulating pattern (I) may be thicker than the wiring pattern (P). For example, the wiring pattern (P) may be a protruding pattern disposed on the upper surface of the first insulating layer 111, and therefore, to protect the same, the insulating pattern (I) may be formed to be thicker than the wiring pattern (P) before processing the cavity (C). However, the wiring pattern (P) may be a buried pattern buried in the upper surface of the first insulating layer 111 such that the upper surface thereof is exposed, and in this case, the thickness of the insulating pattern (I) may not be particularly limited. The thickness may be measured using a scanning microscope or an optical microscope, such as an Olympus optical microscope (×1,000), based on the polished or cut cross section of the printed circuit board 100, and in the case in which the thickness is not constant, the size relationship may be determined by the average value of the thickness measured at five random points.

A portion of the side surface of the insulating pattern (I) exposed by the cavity (C) may be substantially coplanar with the wall surface of the cavity (C). Substantially coplanar may include not only a complete coplanar case, but also a roughly coplanar case in consideration of process errors and the like. In this manner, at least a portion of the insulating pattern (I) may be buried in the second insulating layer 112 in a form that does not protrude on the wall surface of the cavity (C). The insulating pattern (I) may include a thermosetting resist material. For example, the insulating pattern (I) may be formed by applying a thermosetting resist ink. The thermosetting resist ink may be a thermosetting ink that is removed in response to NaOH, rather than a thermosetting ink that is removed in response to Na₂CO₃+H₂O.

The cavity (C) may have a through-cavity shape penetrating between the upper and lower surfaces of the second insulating layer 112. Therefore, it is possible to effectively prevent the occurrence of foot in the cavity C. When the cavity (C) is in the form of such a through-cavity, the cavity (C) may expose at least a portion of the upper surface of the first insulating layer 111.

As required, the printed circuit board 100 according to an example may further include a plurality of first wiring layers 121 respectively disposed on or in the first insulating layer 111, and a plurality of first via layers 131 respectively disposed in the first insulating layer 111 and electrically connecting the plurality of first wiring layers 121 to each other. Among the plurality of first wiring layers 121, an uppermost and/or lowermost layer may protrude upwardly of the first insulating layer 111, but the present disclosure is not limited thereto, and the uppermost and/or lowermost layer may be buried in the first insulating layer 111. Among the plurality of first wiring layers 121, the uppermost layer may include the wiring pattern (P). The first insulating layer 111, the plurality of first wiring layers 121, and the plurality of first via layers 131 may have a coreless substrate shape, but are not limited thereto, and if necessary, may have a core substrate shape having a core layer.

As needed, the printed circuit board 100 according to an example may further include a second wiring layer 122 disposed on the upper surface of the second insulating layer 112, and a second via layer 132 disposed in the second insulating layer 112 and electrically connecting the second wiring layer 122 to the plurality of first wiring layers 121. In addition, the printed circuit board 100 may further include a first resist layer 114 disposed on the upper surface of the second insulating layer 112 and including a first opening h1 exposing the cavity (C) and a second opening h2 exposing at least a portion of the second wiring layer 122. In addition, the printed circuit board 100 may further include a third insulating layer 113 disposed on the lower surface of the first insulating layer 111, a third wiring layer 123 disposed on the lower surface of the third insulating layer 113, and a third via layer 133 disposed in the third insulating layer 113 and electrically connecting the third wiring layer 123 to the plurality of first wiring layers 121. In addition, the printed circuit board 100 may further include a second resist layer 115 disposed on the lower surface of the third insulating layer 113 and including a third opening h3 exposing at least a portion of the third wiring layer 123.

Hereinafter, components of the printed circuit board 100 according to an example will be described in more detail with reference to the drawings.

Each of the first to third insulating layers 111, 112, and 113 may include an insulating material. Examples of insulating materials may include thermosetting resins such as epoxy resins, thermoplastic resins such as polyimide, materials in which these insulating resins are mixed with inorganic fillers such as silica, or a resin impregnated into a core material such as glass fiber (glass cloth, glass fabric) together with an inorganic filler, for example, Ajinomoto Build-up Film (ABF), prepreg, or the like, but the present disclosure is not limited thereto. The first insulating layer 111 may be comprised of a plurality of insulating layers, and the boundaries of these insulating layers may be separated from each other or integrated such that the boundaries may not be distinguished. The number of layers of the plurality of insulating layers is not particularly limited. The plurality of insulating layers may include substantially the same insulating material as each other, but the present disclosure is not limited thereto. A detailed material of the first insulating layer 111 may be different from a material of the second and third insulating layers 112 and 113, but the present disclosure is not limited thereto. The second and third insulating layers 112 and 113 may include substantially the same insulating material, but are not limited thereto. Substantially the same insulating material may be an insulating material of the same trade name. In one example, the first to third insulating layers 111, 112, and 113 may include an insulating material different from that of the insulating pattern (I).

The first and second resist layers 114 and 115 may be disposed on the outermost side of the printed circuit board 100 to protect internal components. The material of the first and second resist layers 114 and 115 is not particularly limited. For example, an insulating material may be used. In this case, a solder resist may be used as the insulating material, but is not limited thereto. A liquid type or film type may be used as the solder resist.

The first to third wiring layers 121, 122, and 123 may perform various functions according to the design of each corresponding layer, and for example, may include a ground pattern, a power pattern, a signal pattern, and the like. In this case, the signal pattern may include various signals other than a ground pattern and a power pattern, for example, a data signal. Each of these patterns may include a line pattern, a plane pattern, and/or a pad pattern. For example, the wiring pattern (P) may include a pad pattern. Each of the first to third wiring layers 121, 122, and 123 may include a metal material. As the metal material, copper (Cu), aluminum (Al), silver (Ag), tin (Sn), gold (Au), nickel (Ni), lead (Pb), titanium (Ti), or alloys thereof may be used. The first to third wiring layers 121, 122, and 123 may respectively include an electroless plating layer (or chemical copper) and an electrolytic plating layer (or electrolytic copper), and may further include copper foil if necessary. The first wiring layer 121 may be comprised of a plurality of layers, and the detailed number of layers is not particularly limited.

The first to third via layers 131, 132, and 133 may respectively perform various functions according to the design of the corresponding layer, and for example, may include ground vias, power vias, signal vias, and the like. In this case, the signal vias may include vias for transferring various signals, for example, data signals, excluding ground vias and power vias. Each of the first to third via layers 131, 132, and 133 may include a metal material. As the metal material, copper (Cu), aluminum (Al), silver (Ag), tin (Sn), gold (Au), nickel (Ni), lead (Pb), titanium (Ti), or alloys thereof may be used. The first to third via layers 131, 132, and 133 may each include an electroless plating layer (or chemical copper) and an electrolytic plating layer (or electrolytic copper), but the present disclosure is not limited thereto. Each of the first to third via layers 131, 132, and 133 may be a filled type in which a via hole is filled with a metal material, but the present disclosure is not limited thereto. For example, the first to third via layers 131, 132, and 133 may be a conformal type in which a metal material is disposed along the wall surface of the via hole. The first to third via layers 131, 132, and 133 may each have a tapered shape in the same direction and/or in opposite directions on a cross section. The first via layer 131 may be comprised of a plurality of layers, and the detailed number of layers is not particularly limited.

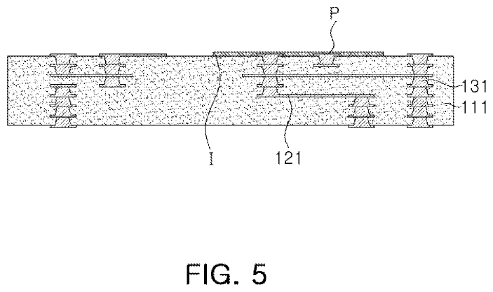

FIGS. 5 to 10 are process cross-sectional views schematically illustrating an example of manufacturing the printed circuit board of FIG. 3.

Referring to FIG. 5, first, a plurality of first wiring layers 121 and a plurality of first via layers 131 are formed on the first insulating layer 111 by using a coreless process or the like. Next, an insulating pattern (I) covering the wiring pattern P is formed on the upper surface of the first insulating layer 111. The insulating pattern (I) may be formed by applying a thermosetting resist ink. Unlike photoresists, thermosetting resists react with sodium hydroxide (NaOH) and may be easily removed.

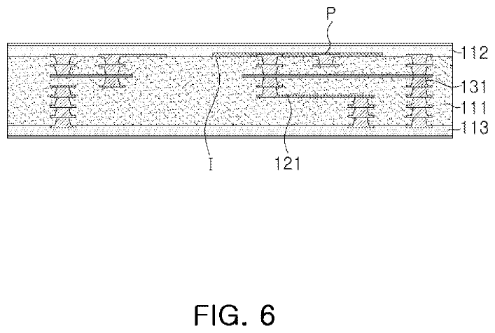

Referring to FIG. 6, second and third insulating layers 112 and 113 are formed on the upper and lower surfaces of the first insulating layer 111, respectively. In detail, the second insulating layer 112 covering the uppermost first wiring layer 121 and the insulating pattern (I) is formed on the upper surface of the first insulating layer 111. In addition, a third insulating layer 113 covering the lowermost first wiring layer 121 is formed on the lower surface of the first insulating layer 111. The first and second insulating layers 112 and 113 may be formed by laminating Resin Coated Copper (RCC) containing the aforementioned insulating material.

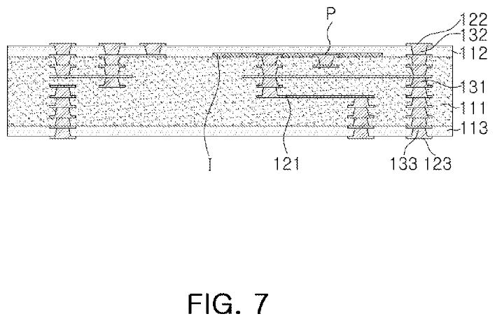

Referring to FIG. 7, second and third wiring layers 122 and 123 and second and third via layers 132 and 133 are formed on the second and third insulating layers 112 and 113, respectively. The second and third wiring layers 122 and 123 and the second and third via layers 132 and 133 may be formed by a wiring forming process such as an Additive Process (AP), Semi AP (SAP), Modified SAP (MSAP), Tenting (TT), or the like after respectively processing via holes in the second and third insulating layers 112 and 113 by laser processing or the like.

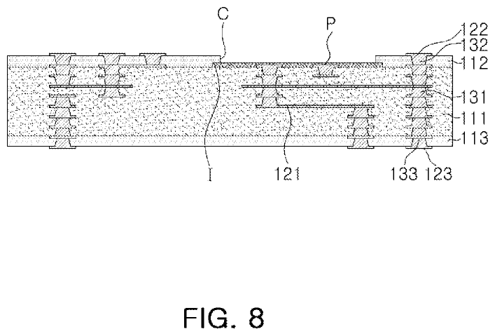

Referring to FIG. 8, a cavity (C) is formed in the second insulating layer 112 by laser processing such as a CO₂ drill. In this case, the insulating pattern (I) may protect the wiring pattern (P). Therefore, the cavity (C) may be formed in the form of a through-cavity by laser processing under stronger conditions, and as a result, the occurrence of foot may be effectively prevented.

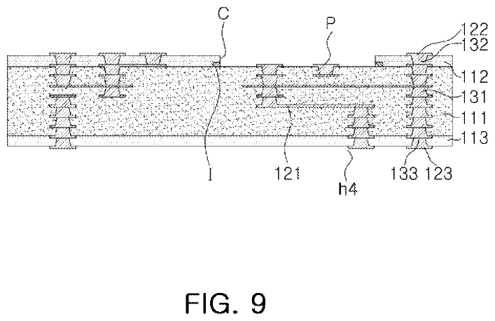

Referring to FIG. 9, a portion of the insulating pattern (I) exposed by the cavity (C) is removed. Sodium hydroxide (NaOH) may be used to remove the insulating pattern (I). Since the insulating pattern (I) may be peeled off using sodium hydroxide (NaOH) instead of other strong peeling chemicals, damage to the wiring pattern (P) may be significantly reduced.

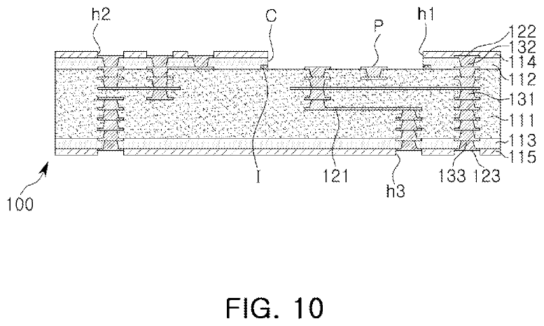

Referring to FIG. 10, first and second resist layers 114 and 115 are formed on the second and third insulating layers 112 and 113, respectively. The first and second resist layers 114 and 115 may be formed by applying a liquid-type solder resist material and then curing the same, or may be formed by laminating a film-type solder resist material. In addition, first and second openings h1 and h2 and a third opening h3 are formed in the first and second resist layers 114 and 115, respectively. The first to third openings h1, h2, and h3 may be formed by various methods depending on the type of insulating material, such as photolithography, laser processing, and mechanical drilling.

Although the printed circuit board 100 according to the above example may be manufactured through a series of processes, the manufacturing method is not limited thereto. In addition, other contents are substantially the same as those described above, and redundant descriptions will be omitted.

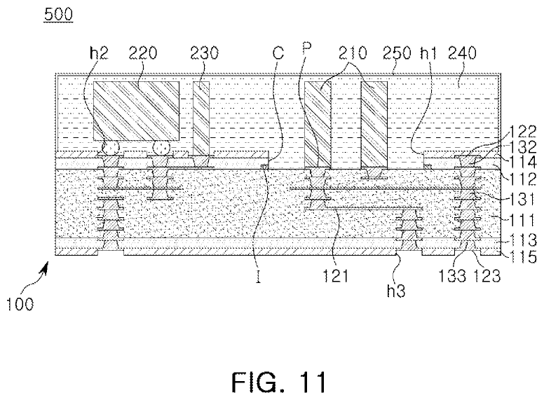

FIG. 11 is a cross-sectional view schematically illustrating another example of a printed circuit board. Referring to the drawings, a printed circuit board 500 according to another example has a package shape. For example, a plurality of electronic components 210, 220, and 230 may be mounted on the printed circuit board 100 according to the above-described example, and the plurality of electronic components 210, 220, and 230 may be molded by a molding material 240. A metal layer 250 may be disposed on the outer surface of the molding material 240 to shield electromagnetic waves, but the present disclosure is not limited thereto.

The first electronic component 210 may be disposed on the cavity (C) and the first opening h1. The first electronic component 210 may be electrically connected to the wiring pattern (P) through a conductive adhesive, for example, soldering. The first electronic component 210 may be a high-capacity passive component, for example, a power inductor, but is not limited thereto. The first electronic component 210 may be thicker than the second and third electronic components 220 and 230, and in the printed circuit board 500 according to another example, since the thick first electronic component 210 is disposed in the cavity C, the overall thickness of the package may be reduced. The thickness may be measured using a scanning microscope or an optical microscope, such as Olympus's optical microscope (×1,000), based on the polished or cut cross section of the printed circuit board 500, and in the case in which the thickness is not constant, the size relationship may be determined by the average value of the thickness measured at five random points.

The second electronic component 220 may be disposed on the second opening h2. The second electronic component 220 may be electrically connected to at least an exposed portion of the second wiring layer 122 through a conductive member, such as a solder ball. The second electronic component 220 may be an integrated circuit (IC) die in which hundreds to millions of elements are integrated into a single chip. The integrated circuit die may be formed based on an active wafer, and in this case, silicon (Si), germanium (Ge), gallium arsenide (GaAs), or the like may be used as a base material constituting each body. Various circuits may be formed in the body. A connection pad may be formed on each body, and the connection pad may include a conductive material such as aluminum (Al) or copper (Cu). The integrated circuit die may be a bare die or a packaged die.

The third electronic component 230 may be disposed on anther second opening h2. The third electronic component 230 may be electrically connected to at least another exposed portion of the second wiring layer 122 through a conductive adhesive, for example, soldering. The third electronic component 230 may be other passive components, for example, MLCC or the like, but is not limited thereto.

A molding material 240 may protect the plurality of electronic components 210, 220, and 230. The material of the molding material 240 is not particularly limited, and a known molding material such as Epoxy Molding Compound (EMC) may be used.

The metal layer 250 may have functions such as electromagnetic wave shielding and heat dissipation, and to this end, may include a metal material such as copper (Cu), aluminum (Al), silver (Ag), tin (Sn), gold (Au), nickel (Ni), lead (Pb), titanium (Ti), or alloys thereof. The metal layer 250 may be formed to have a relatively thin thickness by sputter plating or the like, but the present disclosure is not limited thereto.

In addition, other contents are substantially the same as those described above in the printed circuit board 100 according to an example, and thus, redundant descriptions are omitted.

In the present disclosure, the meaning of “on a cross-section” may refer to a cross-sectional shape when an object is vertically cut, or a cross-sectional shape when the object is viewed from a side-view. In addition, the meaning of “on a plane” may be a shape when the object is horizontally cut, or a plane shape when the object is viewed from a top-view or bottom-view.

In the present disclosure, the lower side, lower portion, lower surface, and the like are used to mean directions toward the mounting surface of the semiconductor package including the organic interposer based on the cross section of the drawing for convenience, and the upper side, upper portion, upper surface and the like are used in the opposite direction. However, this is the definition of the direction for convenience of description, and the scope of the claims is not particularly limited by the description of this direction, of course.

As set forth above, according to an embodiment, a printed circuit board in which damage to wiring patterns exposed by cavities and footing in cavities may be prevented may be provided.

In the present disclosure, the meaning of being connected is a concept including not only being directly connected but also being indirectly connected through an adhesive layer or the like. In addition, the meaning of being electrically connected is a concept that includes both physically connected and non-connected cases. In addition, expressions such as first and second are used to distinguish one component from another, and do not limit the order and/or importance of the components. In some cases, without departing from the scope of rights, the first component may be named a second component, and similarly, the second element may be referred to as the first element.

The expression “an (one) example” used in the present disclosure does not mean the same embodiments, and is provided to emphasize and describe different unique characteristics. However, the examples presented above are not excluded from being implemented in combination with features of other examples. For example, even if a matter described in a specific example is not described in another example, it may be understood as a description related to another example, unless there is a description contrary to or contradictory to the matter in the other example.

Terms used in this disclosure are only used to describe an example, and are not intended to limit the disclosure. In this case, singular expressions include plural expressions unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
a first insulating layer;
a wiring pattern disposed in an upper side of the first insulating layer;
a second insulating layer disposed on an upper surface of the first insulating layer and having a cavity exposing the wiring pattern; and
an insulating pattern disposed between the first and second insulating layers, and having a side surface partially exposed by the cavity, while having an upper surface entirely covered by the second insulating layer.

2. The printed circuit board of claim 1, wherein the insulating pattern is disposed on the upper surface of the first insulating layer and at least partially buried in the second insulating layer, and a portion of the side surface of the insulating pattern is exposed from the second insulating layer, and a remaining part of the side surface is covered with the second insulating layer.

3. The printed circuit board of claim 1, wherein a portion of the side surface of the insulating pattern exposed by the cavity is substantially coplanar with a wall surface of the cavity.

4. The printed circuit board of claim 1, wherein the insulating pattern is disposed to surround the cavity.

5. The printed circuit board of claim 1, wherein the insulating pattern has a thickness greater than a thickness of the wiring pattern.

6. The printed circuit board of claim 1, wherein the cavity penetrates between an upper surface and a lower surface of the second insulating layer.

7. The printed circuit board of claim 6, wherein the cavity exposes at least a portion of the upper surface of the first insulating layer.

8. The printed circuit board of claim 1, further comprising:
a plurality of first wiring layers respectively disposed on or within the first insulating layer; and
a plurality of first via layers respectively disposed within the first insulating layer and connecting the plurality of first wiring layers to each other,
wherein an uppermost layer among the plurality of first wiring layers includes the wiring pattern.

9. The printed circuit board of claim 8, further comprising:
a second wiring layer disposed on an upper surface of the second insulating layer; and
a second via layer disposed within the second insulating layer and connecting the second wiring layer to the plurality of first wiring layers.

10. The printed circuit board of claim 9, further comprising a first resist layer disposed on the upper surface of the second insulating layer and including a first opening exposing the cavity and a second opening exposing at least a portion of the second wiring layer.

11. The printed circuit board of claim 10, further comprising:
a first electronic component disposed on the cavity and the first opening and connected to the wiring pattern; and
a second electronic component disposed on the second opening and connected to the at least a portion of the second wiring layer.

12. The printed circuit board of claim 11, further comprising;
a molding material covering the first and second electronic components; and
a metal layer disposed on an outer surface of the molding material.

13. The printed circuit board of claim 8, further comprising:
a third insulating layer disposed on a lower surface of the first insulating layer;
a third wiring layer disposed on a lower surface of the third insulating layer; and
a third via layer disposed within the third insulating layer and connecting the third wiring layer to the plurality of first wiring layers.

14. The printed circuit board of claim 13, further comprising a second resist layer disposed on the lower surface of the third insulating layer and including a third opening exposing at least a portion of the third wiring layer.

15. A printed circuit board comprising:
a first insulating layer;
a wiring pattern disposed in an upper side of the first insulating layer;
a second insulating layer disposed on an upper surface of the first insulating layer and having a cavity exposing the wiring pattern; and
an insulating pattern disposed along a wall surface of the cavity, at least partially buried in the second insulating layer, and including a thermosetting resist material.

16. The printed circuit board of claim 15, wherein the thermosetting resist material reacts faster to sodium hydroxide (NaOH) than the wiring pattern or the second insulating layer.

17. A printed circuit board comprising:
a first insulating layer;
a wiring pattern protruding from an upper surface of the first insulating layer;
an insulating pattern protruding from the upper surface of the first insulating layer; and
a second insulating layer disposed on the upper surface of the first insulating layer to cover the insulating pattern and having a cavity exposing the wiring pattern and at least a portion of the insulating pattern.

18. The printed circuit board of claim 17, wherein the insulating pattern surrounds the cavity.

19. The printed circuit board of claim 17, wherein the insulating pattern has a thickness greater than a thickness of the wiring pattern.

20. The printed circuit board of claim 17, further comprising:
a second wiring layer disposed on an upper surface of the second insulating layer; and
a second via disposed in the second insulating layer and connecting the second wiring layer to another wiring pattern protruding from the upper surface of the first insulating layer.

21. The printed circuit board of claim 20, further comprising a first resist layer disposed on the upper surface of the second insulating layer and including a first opening exposing the cavity and a second opening exposing at least a portion of the second wiring layer.

22. The printed circuit board of claim 21, further comprising:
a first electronic component disposed on the cavity and the first opening and connected to the wiring pattern; and
a second electronic component disposed on the second opening and connected to the at least a portion of the second wiring layer.

23. The printed circuit board of claim 20, wherein an inclination angle of a wall surface of the cavity with respect to the upper surface of the first insulating layer is greater than an inclination angle of a wall surface of the second via with respect to the upper surface of the first insulating layer.
